(19) United States
(12) Patent Application Publication
(10) Pub. No.: US 2007/0090710 A1
(43) Pub. Date: Apr. 26, 2007

(54) DC brush-free motor and fan rotated by outer rotor having annular ferrite magnet with alignment on its inner periphery

(75) Inventor: Chi-Wen Chen, Taipei City (TW)

Correspondence Address: BACON & THOMAS, PLLC, 625 SLATERS LANE, FOURTH FLOOR, ALEXANDRIA, VA, 22314, US

(73) Assignee: SUPER ELECTRONICS CO., LTD, Taipei City (TW)

(21) Appl. No.: 11/494,482

(22) Filed: Jul. 28, 2006

(30) Foreign Application Priority Data
Oct. 21, 2005 (TW) 094218279

(51) Int. Cl. H02K 7/00; H02K 21/12; H01L 41/00

(52) U.S. Cl. 310/156.26; 310/156.43; 417/423.7; 310/67 R; 310/354

(57) ABSTRACT

A DC brush-free motor or fan rotated by an outer rotor having an annular ferrite magnet with grain alignment on its inner periphery, the main body of the motor or fan is composed of a base, a stator and an outer rotor surrounding the stator; the outer rotor includes a rotating disk and the annular ferrite magnet fixed on an inner periphery of the rotating disk, the annular ferrite magnet is a multipolar anisotropic permanent magnet, the main body of the annular magnet is divided into a magnetic conductive outer layer which is not magnetic and a magnetic inner layer, fluxes of the inner layer turn back when they pass the outer layer to thereby shorten the magnetic loops, and to increase magnetic force and the effect of magnetic energy accumulation. When the motor runs, the outer rotor drives a rotating axle (on the base) extended out of a housing to put out power and to be a power output axle of the motor. As to the fan, the outer rotor is provided on its outer portion with fan blades, an effect of air blowing can be achieved by rotating the fan blades.

### BACKGROUND OF THE INVENTION

1. Field of the Invention

The present invention relates to a DC brush-free motor or a fan rotated by an outer rotor, and especially to a DC brush-free motor or a fan having an annular ferrite magnet with grain alignment on its inner periphery in order to increase magnetic force and the effect of magnetic energy accumulation, and further to increase the efficiency of the DC brush-free motor and the fan.

2. Description of the Prior Art

According to the evaluation of the Electric Power Researching Institution of the U.S.A., consumption of electric energy in the recent years has been 40% of the amount of total energy source consumption, and the ratio of supplying electric energy for electric appliances is largely raised following the rising of the quality of living.

It is estimated that by the year of 2010, there will be 80% of energy source to supply for electric appliances, wherein energy source consumption of motors will occupy 55% of total energy source consumption; in view of this, to develop motors with high reliability and good performances has been necessary measures for increasing competitiveness of a country.

Among various kinds of motors, by the fact that DC brush-free motors adopt electronic phase changing structures which makes the speed of the motors get up to 10,000 rpm; the wide range of speed of it, the low inertia of the rotor, the low electromagnetic interference, the saving of carbon brush maintenance and the eliminating of carbon brush powder dust are all the advantages of the DC brush-free motors; and they are the motors necessary for using in CNC tooling machines, semi-conductor processing equipment in the field of high preciseness of control.

Additionally, because of rapid technical advance and popularly using of specific controlling IC for brush-free motors, the brush-free motors get superiority in price; some domains of conventional induction motors have been gradually substituted by the DC brush-free motors, such as those dustless indoor fan motors for chemical engineering, household application or building application, those heat sinking fan motors like air-conditioner fan motors, ceiling fan motors, compressor motors, washing machine direct-driving motors, building constant-pressure pump motors and consumptive electronic products (such as projectors, computer fans) etc., it is thereby evident that in the future, DC brush-free motors and fans will predominate in these industries.

However, the outer rotor magnet used presently in each of those DC brush-free motors and fans rotated by an outer rotor mostly uses the neodymium iron boron (NdFeB) series; such material is made by mixing 94% neodymium iron boron (NdFeB) and 6% nylon, it is formed an annular member by injection molding, 28 pole positions in the inner periphery of the annular member are magnetized to form an annular magnet having 28 poles. The magnetic characteristics of such material surely can satisfy requirements, but it has a defect in having high cost (neodymium is rare metal with smaller yield of production) and is difficult to be produced, hence an article made of it is quite expensive.

Therefore, manufacturers use magnets made of/by ferrite magnet material/anisotropic/wet punching shaping mode in lieu of the neodymium iron boron (NdFeB) magnets to lower their costs. By the problem resided in technical processing of such outer rotor magnets, such magnets can only be used to make lunar anisotropic ferrite magnets and then at least three of such lunar magnets are assembled to form an annular shape. These annular permanent magnets assembled from the lunar anisotropic ferrite magnets have the following grave defects in their functions:
1. In assembling, an air gap will be formed between every two magnets to be subjected to inducing magnetic leakage; hence cogging will be induced during running of the annular permanent magnets.
2. By virtue that the annular permanent magnets are each formed from several lunar magnets, their work of processing and assembling is more time consumptive, and their inner roundness is inferior.
3. the surface magnetic flux density of the magnets formed of neodymium iron boron (NdFeB) by injection molding is 2100˜2300 Gauss, while that of the magnets made from ferrite magnets is only 1650˜1950 Gauss which is slight insufficient.
4. The sintering temperature of the ferrite magnets is about 1240° C., the thickness of the sintered magnets shall not be too small, otherwise the magnets is fragile, so that the outer diameter of each assembled annular magnet is larger; this makes a bulky housing of a whole motor and a whole fan.
5. By virtue of the problems of magnetic leakage, cogging, insufficiency of magnetic force and larger outer diameter etc., each permanent annular magnet assembled from lunar anisotropic ferrite magnets is unable yet to get the acknowledgement of meeting the specification; it is less competitive as for an added value to a commodity.

And more, when the composite material of neodymium iron boron (NdFeB) or a lunar anisotropic ferrite magnet is used on a DC brush-free motor rotated by an outer rotor, its magnetic fluxes all pass through an iron rotating disk surrounding the annular magnet and through air, then form magnetic loops with an inner stator, in this mode, loss of magnetic fluxes is very much, thus the effect of a motor and a fan is reduced.

In fact, using an annular magnet assembled from lunar anisotropic permanent ferrite magnets is not bad in addition to its prevalence in price; its physical characteristics are better than those of the magnets formed of the neodymium iron boron (NdFeB) series; it still is the excellent option of material to those industries having higher requirement for the range of temperature, humidity durability and alkali resistance. Besides, the material of a ferrite magnet is produced mainly of the recovered mill scale material obtained from acid washing of steel plates; it more meets the tendency of environmental conservation.

And more, as stated above, speaking only of the magnetic characteristics, the material of a ferrite magnet is inferior than the neodymium iron boron (NdFeB) series. Therefore, if the structure of the annular ferrite magnet is improved and is used as a magnet of an outer rotor on a DC brush-free motor or a fan rotated by an outer rotor, magnetic leakage can be reduced, surface magnetic flux density of the magnet and magnetic field intensity can be increased, meantime the work of processing in assembling can be reduced; thereby the magnetic characteristics of the ferrite magnet can be extremely developed, the ferrite magnet will be able to take the place of the magnet of the neodymium ironboron (NdFeB) series which has smaller yield of production and are expensive; this will bring a revolutional influence on the DC brush-free motors and fans driven by outer rotors to push forward the industry of the art; and this is the ground of studying and developing the structure of the present invention.

### SUMMARY OF THE INVENTION

Particularly, the DC brush-free motor or the fan rotated by an outer rotor having an annular ferrite magnet with grain alignment on its inner periphery of the present invention has a main body, the main body is composed of a base, a stator and an outer rotor surrounding the stator, wherein the base has a rotating axle, the stator further has a set of yokes and an induction coil, the outer rotor is composed of a rotating disk and an annular ferrite magnet with grain alignment on its inner periphery and being fixed on the inner periphery of the rotating disk, the inner peripheral ferrite magnet with grain alignment is a multipolar anisotropic permanent magnet, the main body of the annular ferrite magnet is divided into a magnetic conductive outer layer which is not magnetic and a magnetic inner layer, when electric power enters the stator to make the magnetic poles change alternately, the annular ferrite magnet with grain alignment on its inner periphery can be attracted and repulsed to drive the entire outer rotor to rotate and put out power.

By the above stated rotation and putting out power of the outer rotor, the present invention includes the following two application modes in particular practicing:
1. When it is used on a motor, the base, the stator and the outer rotor stated above are all provided in a housing of the motor, the outer rotor drives the rotating axle on the base, the rotating axle is extended out of the housing to put out power and to be a power output axle of the motor.
2. When it is used on a fan, the outer rotor is directly provided on its outer portion with fan blades; in rotating the outer rotor, the blades of the fan synchronically rotates with the outer rotor, an effect of air blowing can thus be achieved by rotating of the fan blades.

In addition to these, the object of dividing the annular ferrite magnet with grain alignment on its inner periphery into the magnetic inner layer and the magnetic conductive outer layer is to make magnetic fluxes of the magnetic inner layer turn back right away when they pass the magnetic conductive outer layer to thereby shorten the magnetic loops, and to increase magnetic force and the effect of magnetic energy accumulation, and further to increase the efficiency of the DC brush-free motor or the fan rotated by the outer rotor. Not like the mode of the conventional compound material of the neodymium iron boron (NdFeB) magnets or the lunar anisotropic ferrite magnets, when in use of the DC brush-free motor or the fan rotated by an outer rotor, the magnetic fluxes all pass through an iron rotating disk surrounding the annular magnet and through air, then form magnetic loops with the inner stator, in this mode, loss of magnetic fluxes is very much, thus the effect of the motor and the fan is reduced.

The present invention will be apparent from two preferred embodiment thereof after reading the detailed description of the preferred embodiment thereof in reference to the accompanying drawings.

### BRIEF DESCRIPTION OF THE DRAWINGS

FIG. 1 is a sectional schematic view showing the structure of a first preferred embodiment (applied on a DC brush-free motor) rotated by an outer rotor of the present invention;

FIG. 2 is a perspective schematic view showing the magnetic loops of magnetic fluxes of an annular ferrite magnet with grain alignment on its inner periphery;

FIG. 3 is a sectional schematic view showing the structure of a second preferred embodiment (applied on a fan) rotated by an outer rotor of the present invention;

### DETAILED DESCRIPTION OF THE PREFERRED EMBODIMENT

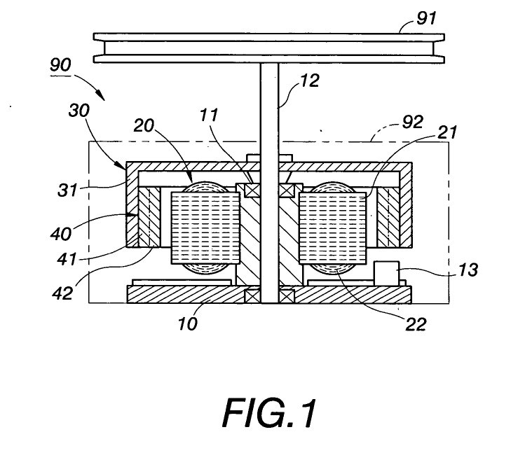

In a first embodiment of the present invention as shown in FIG. 1 which is a perspective view showing the structure of a DC brush-free motor 90 rotated by an outer rotor, the DC brush-free motor 90 puts out power through rotating of a rotating axle. In the drawing, the rotating axle is provided on its front end with a belt pulley 91, when the rotating axle is rotated, the belt pulley 91 is rotated to put out power. Certainly, the front end of the rotating axle can be provided with fan blades or other necessary rotation driving elements.

In this embodiment, the DC brush-free motor 90 rotated by an outer rotor is provided internally with a base 10, a stator 20 and the outer rotor 30 surrounding the stator 20. Wherein:

the base 10 is fixed in a housing 92 of the DC brush-free motor 90 for assembling and positioning of the stator 20 and the outer rotor 30, and is provided centrally with a rotating axle 12 to be rotated by providing of a bearing 11, it is provided on one side of it with a Hall element 13 (magnetic inductive IC), and the rotating axle 12 is extended out of a housing 92 of the motor 90 to connect to the abovementioned belt pulley 91, fan blades or other necessary rotation driving elements; when the rotating axle 12 is rotated, power is put out;

the stator 20 is fixed on the outer periphery of the rotating axle 12, and further has a set of yokes 21 and an induction coil 22, thereby electric power is led into the induction coil 22 in an electronic phase changing mode, this can render the stator 20 to create alternate changing of magnetic poles;

the outer rotor 30 is composed of the rotating disk 31 and an annular ferrite magnet 40 with grain alignment on its inner periphery and being fixed on the periphery of the rotating disk 31, wherein the center of the rotating disk 31 and the rotating axle 12 of the base 10 are fixed, the annular ferrite magnet 40 surrounds the stator and keeps a suitable distance from the Hall element 13 of the base 10; when the annular ferrite magnet 40 of the outer rotor 30 is driven to rotate, by synchronic rotating of the rotating axle 12 in the housing 92 of the motor 90 driven by the rotating disk 31, when the rotating axle 12 is connected to the belt pulley 91, fan blades or other necessary rotation driving elements, power is put out.

By assembling of the above mentioned elements, when electric power is led into the stator 20 in an electronic phase changing mode to create alternate changing of magnetic poles, the multipolar annular ferrite magnet 40 can be attracted and repulsed to drive the entire outer rotor 30 to rotate, and the outer rotor 30 synchronically rotates the rotating axle 12, so that the rotating axle 12 puts out power; the rotating rate of the outer rotor 30 is sensed by the Hall element 13 which puts out a signal for controlling, thereby the motor runs normally.

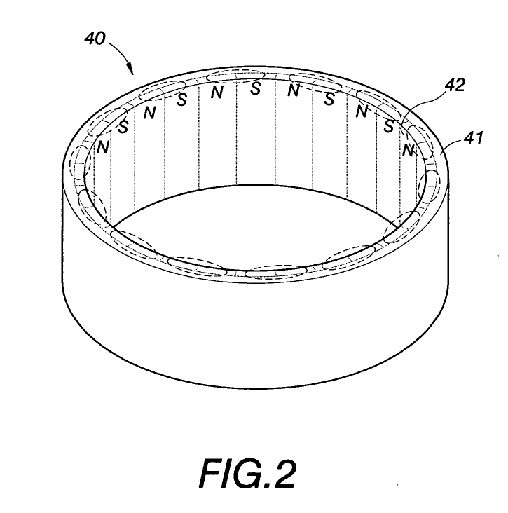

As shown in FIG. 2, the annular ferrite magnet 40 with grain alignment on its inner periphery is a multipolar anisotropic permanent magnet (the fewer the number of poles is, the larger the rotating rate will be), an annular main body of the annular ferrite magnet 40 is divided into a magnetic conductive outer layer 41 which is not magnetic and a magnetic inner layer 42, magnetic fluxes of the magnetic inner layer 42 turn back right away when they pass the magnetic conductive outer layer 41 to thereby shorten the magnetic loops, and to increase magnetic force and the effect of magnetic energy accumulation. Not like the mode of the conventional compound material of the neodymium iron boron (NdFeB) magnets or the lunar anisotropic ferrite magnets, when in use of the DC brush-free motor rotated by an outer rotor, the magnetic fluxes all pass through an iron member surrounding the annular magnet and through air, then form magnetic loops with the inner stator, in this mode, loss of magnetic fluxes is very much, thus the effect of the motor is largely reduced.

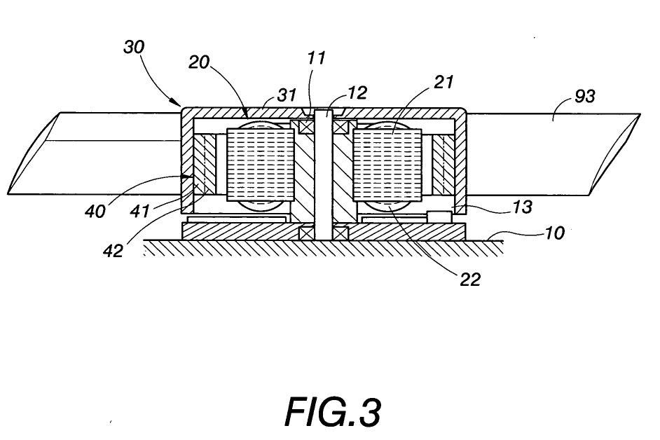

As shown in FIG. 3 which is a sectional schematic the structure of a second preferred embodiment of the present invention which is a fan rotated by an outer rotor, the embodiment also is provided internally with a base 10, a stator 20 and the outer rotor 30 surrounding the stator 20; electric power is led into an induction coil 22 of the stator 20 in an electronic phase changing mode, this can render the entire stator 20 to create alternate changing of magnetic poles; an annular ferrite magnet 40 with grain alignment on its inner periphery and a rotating disk 31 of the outer rotor 30 thus are driven. The principle that the embodiment is based on is same as that of the first preferred embodiment, and no further narration is provided.

The difference between the second preferred embodiment and the first preferred embodiment is: the second preferred embodiment is not provided in a housing of a motor used for driving, and the function of a rotating axle 12 thereof is only used as a central pivot axle for rotation of the outer rotor 30 and is not extended out of the housing to put out power. Besides, an outer edge of a rotating disk 31 of the outer rotor 30 of the second preferred embodiment is provided directly with a plurality of fan blades 93, when a stator 20 drives the annular ferrite magnet 40 of the outer rotor 30 to make rotating of the rotating disk 31 at the same time, the fan blades 93 provided on the outer edge of a rotating disk 31 rotate synchronically therewith, hence wind power is generated by the fan blades 93; and a fan rotated by an outer rotor is formed.

In this preferred embodiment, a magnetic conductive outer layer 41 of the annular ferrite magnet 40 and a magnetic inner layer 42 are still very important elements. By virtue that magnetic fluxes of the magnetic inner layer 42 of the annular ferrite magnet 40 turn back right away when they pass the magnetic conductive outer layer 41, the annular ferrite magnet 40 needs not to have therearound iron material for forming magnetic loops together with the inner stator 20, thereby the rotating disk 31 does not need to be made of metallic magnetic conductive material; in other words, the rotating disk 31 for the fan rotated by an outer rotor and the fan blades 93 can be integrally formed of plastic by injection molding, the inner edge of the rotating disk 31 can afford direct fixing of the annular ferrite magnet 40 with grain alignment on its inner periphery, this can largely reduce the weight of the fan, and especially makes the annular ferrite magnet 40 suit any of various heat sinking fans rotating with high rotating rates, and can reduce the defect of a conventional technique that results eccentricity and vibration by providing iron material.

The names of the elements composing the present invention are only for illustrating a preferred embodiment of the present invention, and not for giving any limitation to the scope of the present invention. It will be apparent to those skilled in this art that various equivalent modifications or changes without departing from the spirit, scope and characteristic of this invention shall fall within the scope of the appended claims and are intended to form part of this invention.

1. A DC brush-free motor rotated by an outer rotor having an annular ferrite magnet with grain alignment on its inner periphery, wherein said motor comprises in a housing thereof:
a base fixed in said housing for assembling and positioning of a stator and an outer rotor, and being provided with a rotating axle extended out of said housing of said motor to put out power;
said stator, fixed on an outer periphery of said rotating axle of said base, and further having a set of yokes and an induction coil; and
said outer rotor, composed of a rotating disk and an annular ferrite magnet with grain alignment on its inner periphery and being fixed on an inner periphery of said rotating disk, said annular ferrite magnet is a multipolar anisotropic permanent magnet surrounding said stator, a main body of said annular ferrite magnet is divided into a magnetic conductive outer layer which is not magnetic and a magnetic inner layer, when electric power enters said stator in an electronic phase changing mode to make magnetic poles change alternately, said multipolar annular ferrite magnet with grain alignment on its inner periphery is attracted and repulsed to drive said outer rotor to rotate and put out power.

2. A fan rotated by an outer rotor having an annular ferrite magnet with grain alignment on its inner periphery, wherein said fan comprises:
a base for assembling and positioning of a stator and an outer rotor, being provided with a rotating axle;
said stator, fixed on an outer periphery of said rotating axle of said base, and further having a set of yokes and an induction coil; and
said outer rotor, composed of a rotating disk and an annular ferrite magnet with grain alignment on its inner periphery and being fixed on an inner periphery of said rotating disk, an outer edge of said rotating disk is provided with a plurality of fan blades, said annular ferrite magnet is a multipolar anisotropic permanent magnet surrounding said stator, a main body of said annular ferrite magnet is divided into a magnetic conductive outer layer which is not magnetic and amagnetic inner layer, when electric power enters said stator in an electronic phase changing mode to make magnetic poles change alternately, said multipolar annular ferrite magnet with grain alignment on its inner periphery is attracted and repulsed to drive said rotating disk and said fan blades to generate wind power.

3. The DC brush-free motor rotatedby an outer rotor having an annular ferrite magnet with grain alignment on its inner periphery as in claim 1, wherein:
said base is provided on one side thereof with a Hall element to sense rotating rate of said annular ferrite magnet with grain alignment on its inner periphery.

4. The fan rotated by an outer rotor having an annular ferrite magnet with grain alignment on its inner periphery as in claim 2, wherein:
said base is provided on one side thereof with a Hall element to sense rotating rate of said annular ferrite magnet with grain alignment on its inner periphery.

5. The fan rotated by an outer rotor having an annular ferrite magnet with grain alignment on its inner periphery as in claim 2, wherein:
said rotating disk and said fan blades are integrally formed of plastic by injection molding.
